(19) United States
(12) Patent Application Publication
(10) Pub. No.: US 2024/0030158 A1
(43) Pub. Date: Jan. 25, 2024

(54) Scribe Edge Protection Structure for Semiconductor Devices

(71) Applicant: Apple Inc., Cupertino, CA (US)

(72) Inventors: Szu-Ying Ho, San Jose, CA (US); Jeng-Wen P Chen, Campbell, CA (US); Hsiu-Ping Wei, San Jose, CA (US)

(21) Appl. No.: 18/355,556

(22) Filed: Jul. 20, 2023

Related U.S. Application Data
(60) Provisional application No. 63/391,950, filed on Jul. 25, 2022.

(51) Int. Cl. H01L 23/00; H01L 23/58; H01L 21/78

(52) U.S. Cl. CPC H01L 23/562; H01L 23/585; H01L 21/78

(57) ABSTRACT

Systems and methods are provided for reducing damage caused by defects from a scribe lane of an integrated circuit, which may arise during or after a silicon wafer is singulated into separate integrated circuits. An integrated circuit may include an active area and a scribe lane. The scribe lane may include a crack energy release zone or a crack take-off zone, or both. The crack energy release zone may dissipate fracture energy in an event that a crack were to form in the scribe lane. The crack take-off zone may, in the event that the crack were to form in the scribe lane, guide the crack out of a surface of the integrated circuit in the crack take-off zone.

### CROSS-REFERENCE TO RELATED APPLICATIONS

This application claims priority to and benefit of U.S. Provisional Application No. 63/391,950, filed Jul. 25, 2022, and entitled “Scribe Edge Protection Structure for Semiconductor Devices,” which is incorporated herein by reference in its entirety for all purposes.

### BACKGROUND

This disclosure relates to systems and methods to protect circuitry of a semiconductor device from periphery damage such as cracking or delamination after a semiconductor wafer is singulated into separate integrated circuit dies.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Integrated circuits are found in a vast array of electronics devices, including computers, handheld devices, wearable devices, vehicles, robotics, and more. An integrated circuit may be formed by patterning circuits onto a silicon wafer in a fabrication process. At various stages of the fabrication process, layers of materials may be added or subtracted on the silicon wafer according to patterns defined by photolithographic masks. The resulting silicon wafer may include numerous individual integrated circuits that have been patterned and which are separated from one another by a scribe lane. To separate the integrated circuits into separate dies, the wafer may be singulated apart along the scribe lanes in a process referred to as “dicing.” The dicing process applies force to the wafer as it is separated. This force can sometimes introduce defects (e.g., delaminations or cracks) that could extend beyond the scribe lanes and into the circuitry of the individual integrated circuits themselves. Although some integrated circuits may contain hard structures at their edges near the scribe lanes that are intended to block cracks, it is still possible that defects may break through during subsequent assembly handling or inside the finished end user product. When this happens, the integrated circuits may be damaged, impacting the functionality of the chip and reducing integrated circuit yield and reliability.

### SUMMARY

A summary of certain embodiments disclosed herein is set forth below. It should be understood that these aspects are presented to provide the reader with a brief summary of these certain embodiments and that these aspects are not intended to limit the scope of this disclosure.

Certain features may be built into the scribe lane to reduce the likelihood that defects may extend into and damage integrated circuits. These features in the scribe lane may not merely block defects at the die edge, but rather may consume the energy of the cracks and/or channel them away from the circuitry of the integrated circuits themselves. For example, a scribe lane may include features that provide a sacrificial crack-propagation path. The sacrificial crack-propagation path may consume fracture energy at the periphery the integrated circuits during manufacturing or product end use. By consuming the fracture energy in the scribe lane, the sacrificial crack-propagation path may confine the damage to a sacrificial region within the scribe lane.

The sacrificial crack-propagation path may include an energy release zone (ERZ) that may consume at least some fracture energy of a crack, a crack take-off zone (CTZ) that may guide the crack out of the silicon wafer, and a crack stop zone (CSZ) that may block the crack from entering the integrated circuit through the scribe lane if the crack does not exit through the crack take-off zone (CTZ). The energy release zone (ERZ) may include a dummy metal pattern of staggered segments parallel to the die edge. The staggered segments may guide the crack through a serpentine path that is longer than a direct path, thereby consuming the fracture energy of the crack. The crack take-off zone (CTZ) may include structures filled with less rigid materials, such as air, to encourage a crack to break through this area. The crack stop zone (CSZ) may form a guard ring of metal layers within the scribe lane or within the integrated circuits along an edge of the scribe. The structures of the crack stop zone (CSZ) may block a crack that does not break out of the crack take-off zone (CTZ).

Additionally or alternatively, some structures of the scribe lane (e.g., structures of the energy release zone (ERZ) or crack take-off zone (CTZ)) may include an artificial separation interface formed between features that are more dense (high fracture toughness (k1C)) and features that are less dense (low fracture toughness (k1C)). The separation interface formed by the difference in feature density may be used to guide a crack in a preferred direction. By angling the separation interface toward an upper or lower edge of the integrated circuit, the crack may be guided toward breaking out of the scribe lane without damaging the active area circuitry of the integrated circuits.

### BRIEF DESCRIPTION OF THE DRAWINGS

Various aspects of this disclosure may be better understood upon reading the following detailed description and upon reference to the drawings described below.

FIG. 1 is a schematic block diagram of an electronic device, in accordance with an embodiment;

FIG. 2 is a front view of a mobile phone representing an example of the electronic device of FIG. 1, in accordance with an embodiment;

FIG. 3 is a front view of a tablet device representing an example of the electronic device of FIG. 1, in accordance with an embodiment;

FIG. 4 is a front view of a notebook computer representing an example of the electronic device of FIG. 1, in accordance with an embodiment;

FIG. 5 are front and side views of a watch representing an example of the electronic device of FIG. 1, in accordance with an embodiment;

FIG. 6 is a schematic diagram of a silicon wafer including a number of integrated circuits separated by scribe lanes, in accordance with an embodiment;

FIG. 7 is a schematic cross-sectional view of the silicon wafer of FIG. 6 across a scribe lane including an energy release zone (ERZ), a crack take-off zone (CTZ), and a crack stop zone (CSZ), in accordance with an embodiment;

FIG. 8 is a flowchart of a method for manufacturing an energy release zone (ERZ) in a scribe lane of a silicon wafer, in accordance with an embodiment;

FIG. 9 is a flowchart of a method for manufacturing a crack take-off zone (CTZ) in a scribe lane of a silicon wafer, in accordance with an embodiment;

FIG. 10A is a schematic diagram of a pattern of structures in a first metal layer through the scribe lane, in accordance with an embodiment;

FIG. 10B is a schematic diagram of a pattern of structures in a second metal layer through the scribe lane, in accordance with an embodiment;

FIG. 10C is a schematic diagram of a pattern of structures in a third metal layer through the scribe lane, in accordance with an embodiment;

FIG. 11A is a schematic diagram of a pattern of vias connected to structures of the first metal layer of FIG. 10A and the second metal layer of FIG. 10B from the perspective of the first metal layer of FIG. 10A, in accordance with an embodiment;

FIG. 11B is a schematic diagram of the pattern of vias connected to structures of the first metal layer of FIG. 10A and the second metal layer of FIG. 10B from the perspective of the second metal layer of FIG. 10B, in accordance with an embodiment;

FIG. 12A is a schematic diagram of a pattern of vias connected to structures of the second metal layer of FIG. 10B and the third metal layer of FIG. 10C from the perspective of the second metal layer of FIG. 10B, in accordance with an embodiment;

FIG. 12B is a schematic diagram of the pattern of vias connected to structures of the second metal layer of FIG. 10B and the third metal layer of FIG. 10C from the perspective of the third metal layer of FIG. 10C, in accordance with an embodiment;

FIG. 13 is a schematic diagram of a uniform pattern of structures of metal layers in a scribe lane, in accordance with an embodiment;

FIG. 14A is a schematic diagram of a pattern of vias connected to structures of a first metal layer of FIG. 13 and a second metal layer of FIG. 13, in accordance with an embodiment; and

FIG. 14B is a schematic diagram of a pattern of vias connected to structures of the second metal layer of FIG. 13 and a third metal layer of FIG. 13, in accordance with an embodiment.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “including” and “having” are intended to be inclusive and mean that there may be additional elements other than the listed elements. Additionally, it should be understood that references to “some embodiments,” “embodiments,” “one embodiment,” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

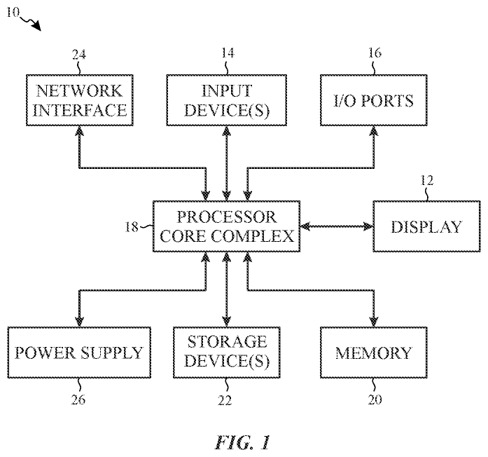

An electronic device 10 that includes at least one integrated circuit is shown in FIG. 1. The electronic device 10 may include numerous components, such as those described below, that may include an integrated circuit that has been manufactured to include a scribe lane with a sacrificial crack-propagation path. This may protect integrated circuit functionality, yield and reliability.

As is described in more detail below, the electronic device 10 may be any suitable electronic device, such as a computer, a mobile phone, a portable media device, a tablet, a television, a virtual-reality headset, a wearable device such as a watch, a vehicle and/or vehicle dashboard, or the like. FIG. 1 is intended to represent one example of a particular implementation and is intended to illustrate the types of components that may be present in an electronic device 10.

The electronic device 10 of FIG. 1 includes an electronic display 12, one or more input devices 14, one or more input/output (I/O) ports 16, a processor core complex 18 having one or more processor(s) or processor cores, local memory 20, a main memory storage device 22, a network interface 24, and a power source 26 (e.g., power supply). The various components described in FIG. 1 may include hardware elements (e.g., circuitry), software elements (e.g., a tangible, non-transitory computer-readable medium storing executable instructions), or a combination of both hardware and software elements. It should be noted that the various depicted components may be combined into fewer components or separated into additional components. For example, the local memory 20 and the main memory storage device 22 may be included in a single component.

The processor core complex 18 is operably coupled with local memory 20 and the main memory storage device 22. Thus, the processor core complex 18 may execute instructions stored in local memory 20 or the main memory storage device 22 to perform operations, such as generating or transmitting image data to display on the electronic display 12. As such, the processor core complex 18 may include one or more general purpose microprocessors, one or more application specific integrated circuits (ASICs), one or more field programmable gate arrays (FPGAs), or any combination thereof.

In addition to program instructions, the local memory 20 or the main memory storage device 22 may store data to be processed by the processor core complex 18. Thus, the local memory 20 and/or the main memory storage device 22 may include one or more tangible, non-transitory, computer-readable media. For example, the local memory 20 may include random access memory (RAM) and the main memory storage device 22 may include read-only memory (ROM), rewritable non-volatile memory such as flash memory, hard drives, optical discs, or the like.

The network interface 24 may communicate data with another electronic device or a network. For example, the network interface 24 (e.g., a radio frequency system) may enable the electronic device 10 to communicatively couple to a personal area network (PAN), such as a Bluetooth network, a local area network (LAN), such as an 802.11x Wi-Fi network, or a wide area network (WAN), such as a 4G, Long-Term Evolution (LTE), or 5G cellular network. The power source 26 may provide electrical power to one or more components in the electronic device 10, such as the processor core complex 18 or the electronic display 12. Thus, the power source 26 may include any suitable source of energy, such as a rechargeable lithium polymer (Li-poly) battery or an alternating current (AC) power converter. The I/O ports 16 may enable the electronic device 10 to interface with other electronic devices. For example, when a portable storage device is connected, the I/O port 16 may enable the processor core complex 18 to communicate data with the portable storage device.

The input devices 14 may enable user interaction with the electronic device 10, for example, by receiving user inputs via a button, a keyboard, a mouse, a trackpad, a touch sensing, or the like. The input device 14 may include touch-sensing components (e.g., touch control circuitry, touch sensing circuitry) in the electronic display 12. The touch sensing components may receive user inputs by detecting occurrence or position of an object touching the surface of the electronic display 12.

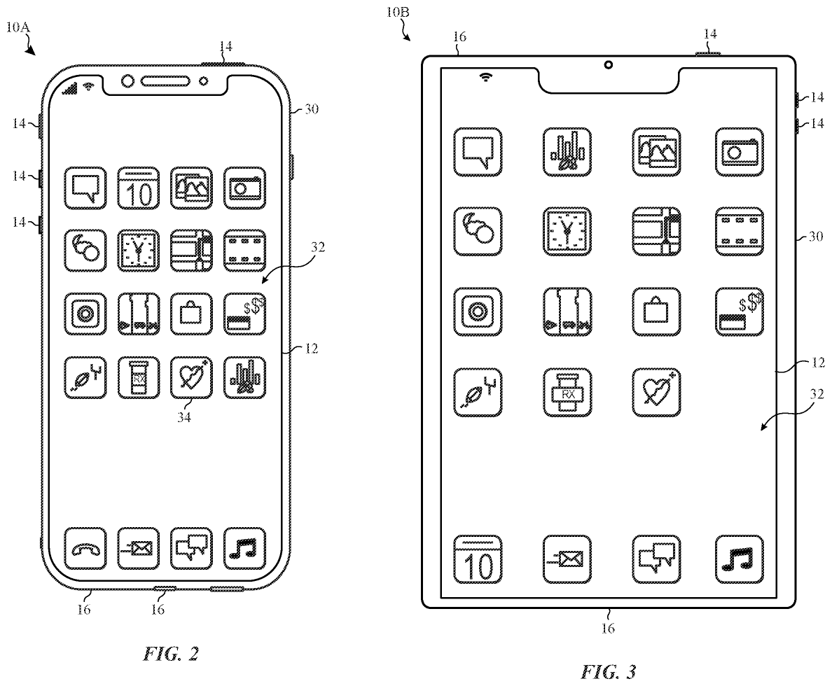

The electronic device 10 may take any suitable form. One example of the electronic device 10 in the form of a handheld device 10A is shown in FIG. 2. The handheld device 10A may be a portable phone, a media player, a personal data organizer, a handheld game platform, or the like. For illustrative purposes, the handheld device 10A may be a smart phone, such as any IPHONE® model available from Apple Inc.

The handheld device 10A includes an enclosure 30 (e.g., housing). The enclosure 30 may protect interior components from physical damage or shield them from electromagnetic interference, such as by surrounding the electronic display 12. The electronic display 12 may display a graphical user interface (GUI) 32 having an array of icons. When an icon 34 is selected either by an input device 14 or a touch-sensing component of the electronic display 12, an application program may launch.

The input devices 14 may be accessed through openings in the enclosure 30. The input devices 14 may enable a user to interact with the handheld device 10A. For example, the input devices 14 may enable the user to activate or deactivate the handheld device 10A, navigate a user interface to a home screen, navigate a user interface to a user-configurable application screen, activate a voice-recognition feature, provide volume control, or toggle between vibrate and ring modes.

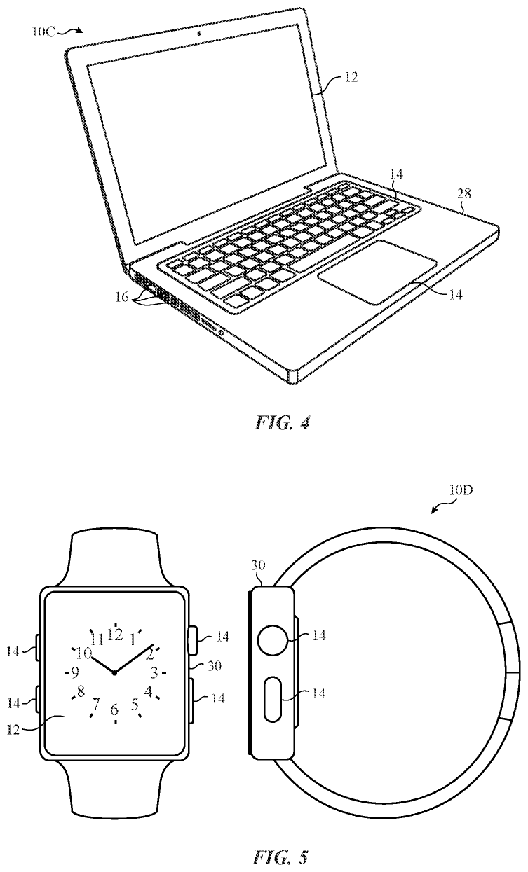

Another example of a suitable electronic device 10, specifically a tablet device 10B, is shown in FIG. 3. The tablet device 10B may be any IPAD® model available from Apple Inc. A further example of a suitable electronic device 10, specifically a computer 10C, is shown in FIG. 4. For illustrative purposes, the computer 10C may be any MACBOOK® or IMAC® model available from Apple Inc. Another example of a suitable electronic device 10, specifically a watch 10D, is shown in FIG. 5. For illustrative purposes, the watch 10D may be any APPLE WATCH® model available from Apple Inc. As depicted, the tablet device 10B, the computer 10C, and the watch 10D each also includes an electronic display 12, input devices 14, I/O ports 16, and an enclosure 30. The electronic display 12 may display a GUI 32. Here, the GUI 32 shows a visualization of a clock. When the visualization is selected either by the input device 14 or a touch-sensing component of the electronic display 12, an application program may launch, such as to transition the GUI 32 to presenting the icons 34 discussed in FIGS. 2 and 3.

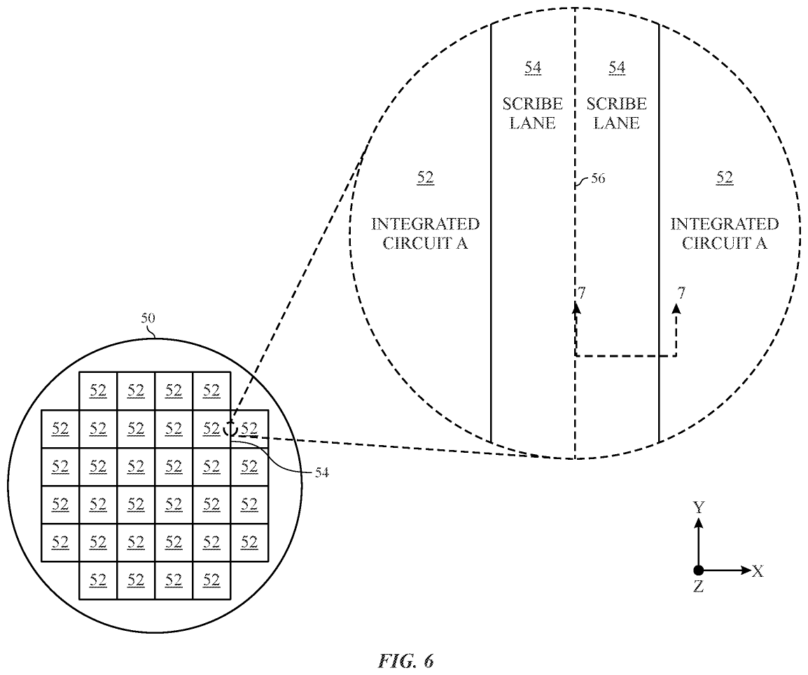

FIG. 6 illustrates a top view of an undiced silicon wafer 50 patterned with numerous individual integrated circuit areas 52 separated by scribe lanes 54. An (x, y, z) coordinate system illustrates a spatial arrangement of the elements of FIG. 6. There may be any suitable number of integrated circuit areas 52 taking any suitable arrangement. The illustration of FIG. 6 is schematic and is intended to illustrate the separation of the individual integrated circuit areas 52 by the scribe lanes 54. In a closer view showing the position of two integrated circuit areas 52 (Integrated Circuit A and Integrated Circuit B) on the silicon wafer 50, the scribe lane(s) 54 include a separation line 56 along which the integrated circuit areas 52 may be singulated apart to form individual dies. The act of separating the silicon wafer 50 to the individual integrated circuit areas 52 could sometimes result in initial cracks that could propagate toward the integrated circuit areas 52 in the following manufacturing processes. As used herein, the term “crack” may refer to any defect (e.g., cracks, fractures, delaminations) that could propagate during or after the singulation process. Accordingly, the scribe lanes 54 may include structures to dissipate fracture energy and/or direct the propagation of cracks out of the scribe lane 54 before the cracks reach the circuitry of the integrated circuit areas 52. In some embodiments, an integrated circuit area 52, is a System-on-Chip (SOC), power management integrated circuit (PMIC), a processor, a chiplet, radio frequency integrated circuit (RFIC) or another logic and/or memory circuitry device.

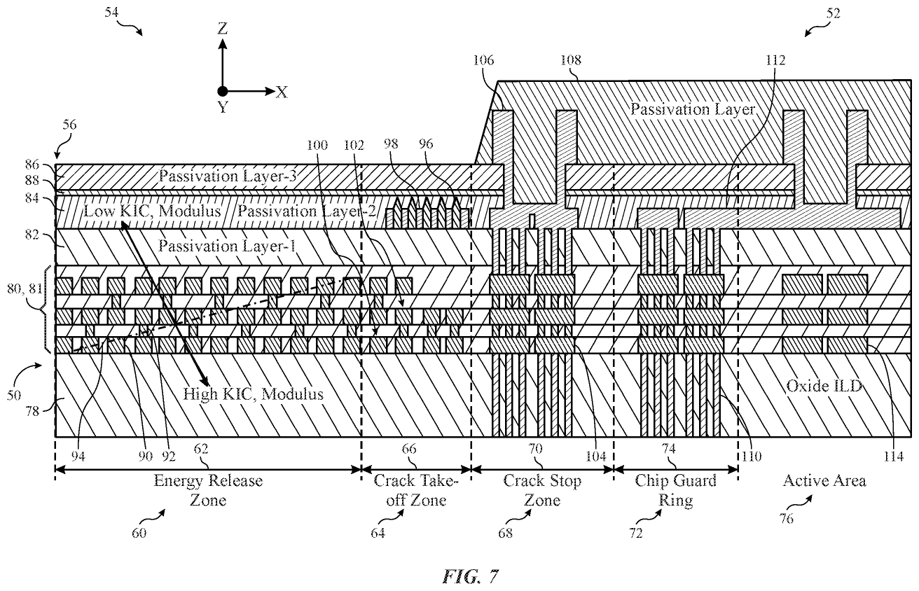

Examples of these structures are shown in FIG. 7, which represents a side view of the scribe lane 54 and integrated circuit area 52 along cut lines 7-7 of FIG. 6. The separation line 56 is shown along a left edge of FIG. 7. It should be appreciated that the structures shown in FIG. 7 represent structures found on one side of the cut line 56 and that comparable (e.g., a mirror image) of structures may also be found on the other side of the cut line 56, though it is not expressly shown here. Moreover, the scribe lanes 54 may also include other circuitry, such as test circuitry. The structures to dissipate fracture energy and/or direct the propagation of cracks out of the scribe lane 54 may be disposed around the other circuitry of the scribe lane 54 and may also be used to protect that circuitry of the scribe lane 54. Moreover, by placing the structures to dissipate fracture energy and/or direct the propagation of cracks out of the scribe lane 54 into otherwise empty spaces around test circuitry, additional overhead in scribe lane 54 width may be avoided.

The scribe lane 54 may include structures that form an energy release zone (ERZ) 60 taking up a first width 62 of the scribe lane 54, a crack take-off zone (CTZ) 64 that take up a second width 66, and a crack stop zone (CSZ) 68 that take up a third width 70. Beyond the crack stop zone (CSZ) 68 of the scribe lane 54 may be the start of circuitry of the integrated circuit area 52, such as a chip guard ring 72 that takes up some outer width 74 of the integrated circuit area 52 and an active area 76 that includes data utilization circuitry of the integrated circuit area 52. If a crack were to propagate into the active area 76, it could damage the function of the integrated circuit area 52. As such, the energy release zone (ERZ) 60, the crack take-off zone (CTZ) 64, and the crack stop zone (CSZ) 68 provide protection against crack propagation from the processes during or after die singulation. The chip guard ring 72 acts as a final check against propagating cracks to block cracks from reaching the active area 76.

While all of these structures are shown in FIG. 7, it should be appreciated that some embodiments may include more or fewer regions. In one example, the scribe lane 54 may include an energy release zone (ERZ) 60 and a crack take-off zone (CTZ) 64 but not a crack stop zone (CSZ). In another example, the scribe lane 54 may include an energy release zone (ERZ) 60 and a crack stop zone (CSZ) 68 but not a crack take-off zone (CTZ) 64. In another example, the scribe lane 54 may include an energy release zone (ERZ) 60 but not a crack take-off zone (CTZ) 64 or a crack stop zone (CSZ) 68. In another example, the scribe lane 54 may include a crack take-off zone (CTZ) 64 and a crack stop zone (CSZ) 68 but not an energy release zone (ERZ) 60. In another example, the scribe lane 54 may include a crack take-off zone (CTZ) 64 but not an energy release zone (ERZ) 60 or a crack stop zone (CSZ) 68.

The purpose of these structures is to cause fracture energy of possible cracks to dissipate and/or to guide cracks to propagate in largely harmless ways. Indeed, to provide more protection than simply may be provided by the chip guard ring 72, the energy release zone (ERZ) 60 may cause cracks to take winding, serpentine paths that dissipate the fracture energy, so that if a crack does reach the chip guard ring 72, it may have too little energy to propagate through. The crack take-off zone (CTZ) 64 may guide the crack to break through and out of the scribe lane 54 before reaching the crack stop zone (CSZ) 68 or the chip guard ring 72. The crack stop zone (CSZ) 68 provides one more layer of protection to block cracks from propagating toward the chip guard ring 72.

The scribe lane 54 and the integrated circuit area 52 are formed from the same layers of the silicon wafer 50. There may be many more layers than those shown in the schematic diagram of FIG. 7; it should be appreciated that the illustrated layers are intended to represent the type of layers that may be used. For example, the silicon wafer 50 may be patterned with an interlayer dielectric (ILD) 78 (e.g., oxide ILD), a number of metal layers 80 and via layers 81, and a variety of passivation layers 82, 84, and 86, some of which may be separated by a dielectric layer 88. The examples used in this disclosure describe metal layers 80 and via layers 81 that include three metal layers 80 (M1, M2, and M3) and two via layers 81 (V12, V23). These layers include various metal structures 90 that may be connected by via 92. However, there may be any suitable number of metal layers 80 and via layers 81 (e.g., 1, 2, 4, 5, 8, 12, 16, 20, 24, or more metal and via layers). The metal structures 90 and vias 92 may be staggered throughout the energy release zone (ERZ) 60 to create meandering paths of least resistance. As a result, cracks that may form during die singulation or in processes after die singulation may propagate around the metal structures 90 and vias 92 in relatively long, serpentine paths, dissipating the fracture energy of the cracks.

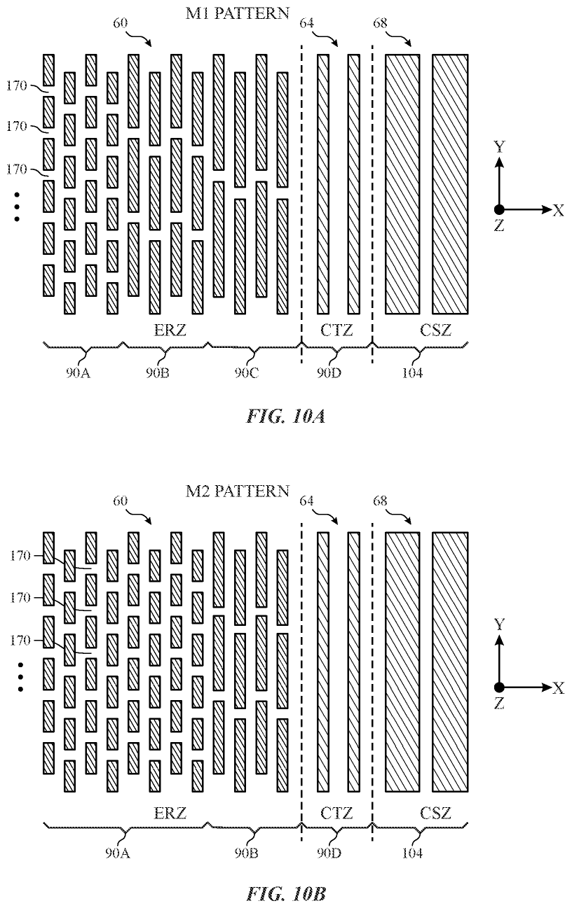

Additionally or alternatively, the metal structures 90 and vias 92 may be arranged to have an artificial separation interface 94 formed by a higher and lower fracture toughness (K1C) and modulus over a slope through the z- and x-directions. The artificial separation interface 94 may guide a crack to preferentially propagate in a direction toward an exit out of a surface of the silicon wafer 50. The metal structures 90 and vias 92 may define the artificial separation interface 94 by being comparatively smaller or shorter (e.g., less dense) above the artificial separation interface 94 and being comparatively larger or longer (e.g., more dense). This will be described further below with reference to FIGS. 10-12.

Continuing with the discussion of FIG. 7, the crack take-off zone (CTZ) 64 may include air gaps 96 formed in the passivation layer 84 and/or a redistribution layer (RDL) 98. Spaces without metal structures 90 or vias 92 that may act as sacrificial regions that encourage cracks to propagate through those areas due to their lower concentration of metal materials. For example, a bottom sacrificial layer 100 having a space without metal structures 90 or vias 92 may guide cracks to a top sacrificial layer 102 that also includes a space without metal structures 90 or vias 92 and out toward the air gaps 96. The air gaps 96 may have any suitable size, shape, and number. Indeed, the air gaps 96 may substantially extend through the height of the passivation layer 84 and/or the redistribution layer (RDL) 98 or may be shorter. While five air gaps 96 are shown, there may be more or fewer (e.g., 1, 2, 3, 4, 6, 10, 20, 50, 100, 200, 500, 1000, or more). By encouraging cracks to exit up and out of the silicon wafer 50 through the air gaps 96, the crack take-off zone (CTZ) 64 may reduce the number of cracks that propagate beyond the crack take-off zone (CTZ) 64.

If a crack did make it past the crack take-off zone (CTZ) 64, the crack stop zone (CSZ) 68 may arrest it. The crack stop zone (CSZ) 68 includes comparatively long and wide metal structures 104 with vias 92 that are relatively tightly connected compared to those of the energy release zone (ERZ) 60 or crack take-off zone (CTZ) 64. Additionally, a trough in a redistribution layer (RDL) and RDL via 106 may protect the integrity of a passivation layer 108. Metal structures connected to the RDL and RDL via 106 may extend vertically through the crack stop zone (CSZ) 68. These structures of the crack stop zone (CSZ) 68 may cause cracks that make it beyond the crack take-off zone (CTZ) 64 to stop. Additionally or alternatively, the structures of the crack stop zone (CSZ) 68 may have the effect of directing cracks away and through the crack take-off zone (CTZ) 64, increasing the likelihood that the cracks may exit the silicon wafer 50 at the crack take-off zone (CTZ) 64.

The chip guard ring 72 may include a variety of additional protective structures 110 that may be connected to another redistribution layer (RDL) 112 of the integrated circuit area 52. The additional protective structures 110 may act as a final guard against cracks to protect circuitry 114 of the active area.

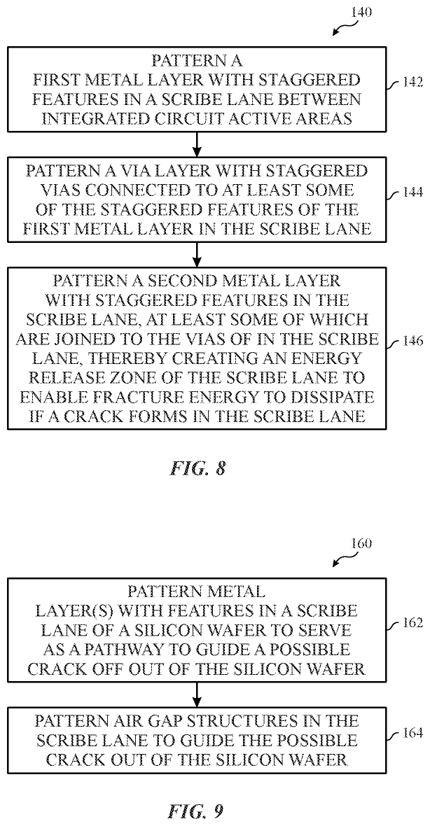

A flowchart 140 of FIG. 8 describes a method of manufacturing a scribe lane that includes an energy release zone (ERZ). While the blocks of the flowchart 140 are described in a particular order, the blocks may take place in any other suitable order. Manufacturing the energy release zone (ERZ) of the scribe lane may involve patterning a first metal layer with staggered features (block 142). A via layer may pattern vias to couple to some of the staggered metal features of the first metal layer (block 144). A second metal layer may be patterned with staggered features and joined to the other staggered metal features of the first metal layer through the vias (block 146). This process may continue for any suitable number of metal layers and via layers. The particular staggered pattern may be selected to guide possible cracks through meandering serpentine paths to cause fracture energy to dissipate.

A flowchart 160 of FIG. 9 describes a method of manufacturing a scribe lane that includes a crack take-off zone (CTZ). The crack take-off zone (CTZ) may be adjacent to an energy release zone (ERZ), in which case the method of the flowchart 160 may take place alongside the method of the flowchart 140, or the crack take-off zone (CTZ) may stand alone without the energy release zone (ERZ). Moreover, while the blocks of the flowchart 160 are described in a particular order, the blocks may take place in any other suitable order. Manufacturing the crack take-off zone (CTZ) of the scribe lane may involve patterning one or more metal layer(s) and via layer(s) with sacrificial layers (e.g., a space without metal structures 90 or vias 92) staggered over a slope through the z- and x-directions where the 1^{st} sacrificial layer closest to separation line 56 and silicon substrate and the last sacrificial layer is in the layer before last metal layer (block 162). Air gaps may be patterned (block 164). The features patterned at block 162 may guide possible cracks toward the air gaps patterned at block 164 to guide the cracks to exit through the surface of the silicon wafer 50.

FIGS. 10A, 10B, and 10C illustrate various patterns of the metal structures 90 and 104 in different metal layers 80 through the energy release zone (ERZ) 60, the crack take-off zone (CTZ) 64, and the crack stop zone (CSZ) 68 that may be used to form the example of FIG. 7. The patterns illustrated in FIGS. 10A, 10B, and 10C represent an example in which the energy release zone (ERZ) 60 includes the artificial separation interface 94 that may guide a crack to preferentially propagate in a direction toward an exit out of a surface of the silicon wafer (e.g., as shown in FIG. 7). FIG. 10A illustrates a pattern of the metal structures 90 and 104 on a lower-level metal layer 80 (e.g., M1), FIG. 10B illustrates a pattern of the metal structures 90 and 104 on a mid-level metal layer 80 (e.g., M2), and FIG. 10C illustrates a pattern of the metal structures 90 and 104 on an upper-level metal layer 80 (e.g., M3). The density of the pattern of the metal structures 90 and 104 is therefore lower on leftward (x-direction) side and higher on rightward (x-direction) side, and pattern this decreases for higher (z-direction) metal layers 80.

To accomplish this, as shown in FIG. 10A, the lower-level metal layer 80 (M1) may include staggered lower-density metal structures 90A, staggered medium-density metal structures 90B, and staggered higher-density metal structures 90C. The metal structures 90A, 90B, and 90C may be formed from the same metal material, but may have different lengths or widths. The metal structures 90A, 90B, and 90C may have lengths of metal material that are parallel to the surface (x-y plane) of the silicon wafer 50. Columns (y-direction) of the metal structures 90A, 90B, and 90C may have gaps 170 that do not align from column to column. For example, the position of the gaps 170 within each group of metal structures 90A, 90B, and 90C may alternate, producing a zig-zag pattern. In other examples, the position of the gaps 170 may vary in other ways but may not align. In some examples, the staggered pattern of the metal structures 90A, 90B, and/or 90C may be arranged 45°/135°, or any other suitable off-axis angles, as opposed to a 0°/90° Manhattan layout. In any event, the staggered pattern creates a path of least resistance for a crack to travel that forms a zig-zag path around the metal structures 90A, 90B, and 90C, thereby dissipating the fracture energy of the crack as it travels a meandering, serpentine path. Metal structures 90D may be much longer (e.g., a full length (y-direction) of the crack take-off zone (CTZ) 64. This may encourage cracks to travel upward rather than around. The crack stop zone (CSZ) 68 has even wider metal structures 104 that may be some multiple wider than the metal structures 90D (e.g., 1.25×, 1.5×, 2×, 3×, 4×, 5×, 10× or more).

In the mid-level metal layer 80 (M2) shown in FIG. 10B, there may be fewer or none of the staggered higher-density metal structures 90C. As shown in FIG. 10B, the staggered lower-density metal structures 90A may take up more of the energy release zone (ERZ) 60 in the mid-level metal layer 80 (M2) and the staggered medium-density metal structures 90B may shift rightward (x-direction) in comparison to those in the lower-level metal layer 80 (M1) shown in FIG. 10A.

In the top-level metal layer 80 (M3) shown in FIG. 10C, there may be fewer or none of the staggered higher-density metal structures 90C or the staggered medium-density metal structures 90B. As shown in FIG. 10C, the staggered lower-density metal structures 90A may take up more (e.g., all) of the space of the energy release zone (ERZ) 60 in the top-level metal layer 80 (M3) in comparison to those in the lower-level metal layer 80 (M1) shown in FIG. 10A or the mid-level metal layer 80 (M2) of FIG. 10B.

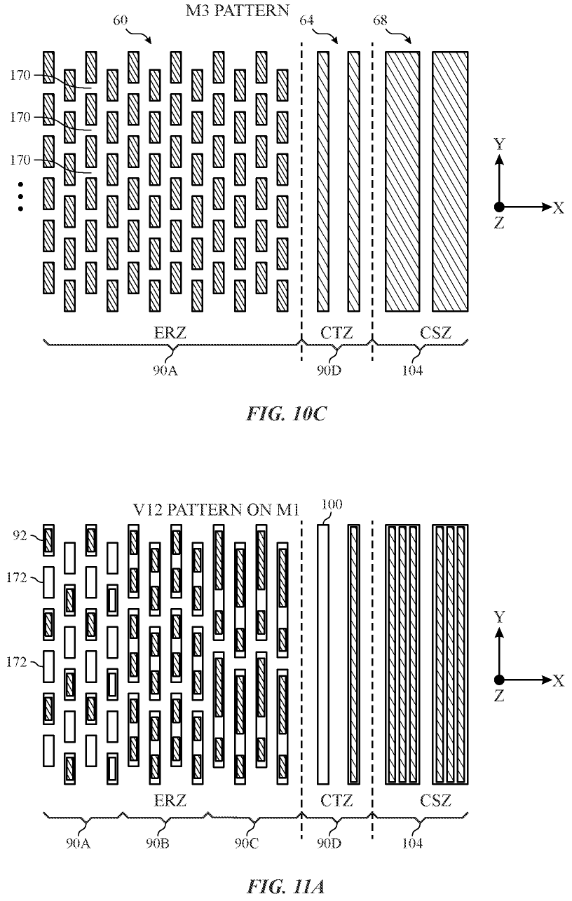

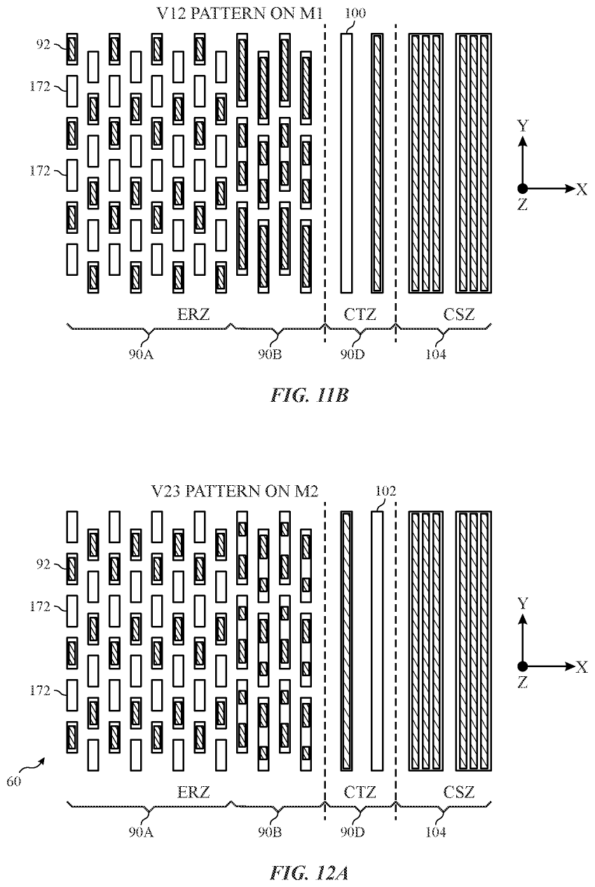

The metal structures 90 from different metal layers 80 may be joined by vias 92 from intervening via layers 81. As shown in FIG. 11A, a via layer 81 (V12) may have a pattern on the lower-level metal layer 80 (M1) that may be more sparse in a first region corresponding to the staggered lower-density metal structures 90A. For example, every other one of the staggered lower-density metal structures 90A may be connected to a via 92 while others may have a via gap 172 where no via is placed. There may be comparatively more vias 92 and comparatively fewer via gaps 172 in a region corresponding to the staggered medium-density metal structures 90B. There may be no via connecting to a first of the metal structures 90D of the crack take-off zone (CTZ) 64. This may correspond to the bottom sacrificial layer 100. The via pattern of the via layer 81 (V12) connects to different metal structures 90 in the mid-level metal layer 80 (M2), as shown in FIG. 11B, but the via pattern remains the same.

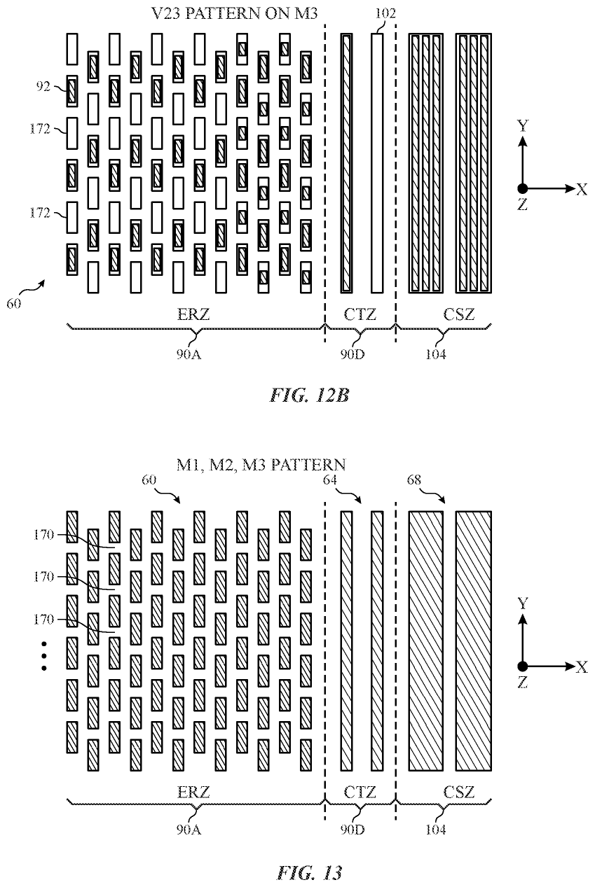

In FIG. 12A, a via layer 81 (V23) is shown to have a pattern on the mid-level metal layer 80 (M2) that may be more sparse in a first region corresponding to the staggered lower-density metal structures 90A, which extend further rightward (x-direction) through the energy release zone (ERZ) 60. For example, every other one of the staggered lower-density metal structures 90A may be connected to a via 92 while others may have a via gap 172 where no via is placed. There may be comparatively more vias 92 and comparatively fewer via gaps 172 in a region corresponding to the staggered medium-density metal structures 90B. Compared to the via layer 81 (V12) shown in FIG. 11A, the corresponding lower density via pattern in the more rightward direction may encourage cracks to gradually travel upward (z-direction) as cracks move closer to the integrated circuit area 52 (in the x-direction). Likewise, there may be a via connecting to a first of the metal structures 90D of the crack take-off zone (CTZ) 64 but not to a second of the metal structures 90D of the crack take-off zone (CTZ) 64. This may correspond to the top sacrificial layer 102. The via pattern of the via layer 81 (V23) connects to different metal structures 90 in the top-level metal layer 80 (M3), as shown in FIG. 12B, but via pattern remains the same.

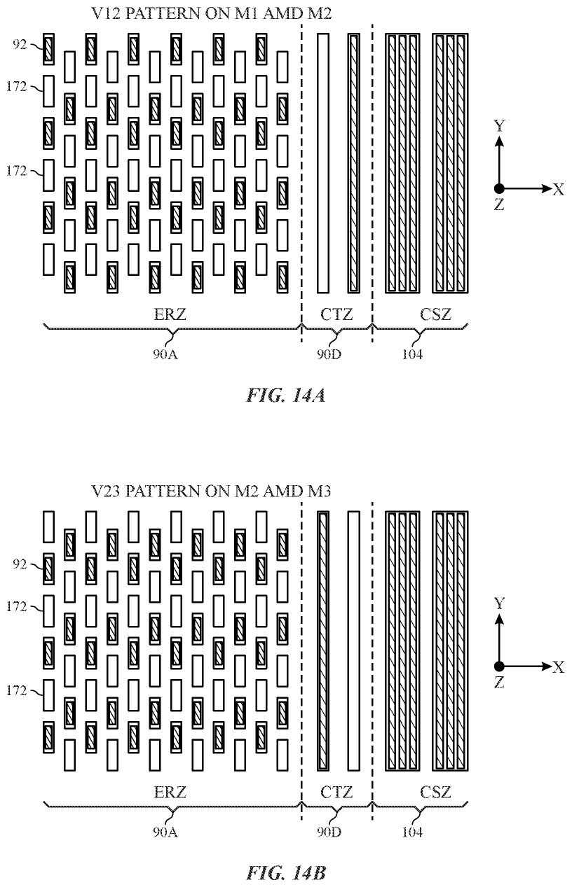

Additionally or alternatively, some number of the metal layers 80 (e.g., M1, M2, M3) may have the same pattern of metal structures 90 and 104, as shown in FIG. 13. For example, the metal layers 80 (e.g., M1, M2, and M3) may have the same or a similar pattern of staggered lower-density metal structures 90A. The metal structures 90D and 104 may be substantially the same as described above with reference to FIGS. 10A, 10B, and 10C. As shown in FIGS. 14A and 14B, different via patterns may be formed between different metal layers 80 to provide a zig-zag pattern in the z-direction. For example, as shown in FIG. 14A, there may be a first via pattern through a first via layer 81 (V12) between the lower-level metal layer 80 (M1) and the mid-level metal layer 80 (M2) that includes vias 92 and via gaps 172, which may be offset from one another (e.g., alternating). As shown in FIG. 14B, there may be a second via pattern through a second via layer 81 (V23) between the mid-level metal layer 80 (M2) and the upper-level metal layer 80 (M3) that includes vias 92 and via gaps 172 offset in the y-direction. This may provide a zig-zag pattern in the z-direction to allow cracks that propagate through to dissipate fracture energy. It should further be appreciated that the via patterns that alternate in the y-direction as shown in FIGS. 14A and 14B may also be used in connection with the patterns shown in FIGS. 10A, 10B, and 10C.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure. For example, there may be more or fewer metal layers that include more or fewer different patterns of metal structures, which may be joined by more or fewer via layers. In any event, the energy release zone may include patterns in which metal structures are not all aligned, which may encourage cracks to take meandering, serpentine paths around the metal structures to dissipate fracture energy.

Moreover, techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. An integrated circuit comprising:
an active area; and
a scribe lane beyond the active area, wherein the scribe lane comprises at least one of:
a crack energy release zone configured to dissipate fracture energy in an event that a crack were to form in the scribe lane; or
a crack take-off zone configured to, in the event that the crack were to form in the scribe lane, guide the crack out of a surface of the integrated circuit in the crack take-off zone.

2. The integrated circuit of claim 1, wherein the crack energy release zone comprises at least one metal layer comprising a plurality of adjacent metal structures offset from one another in a zig-zag pattern.

3. The integrated circuit of claim 1, wherein the crack energy release zone comprises a plurality of metal and via layers with varying fracture toughness or modulus to guide the crack through the crack energy release zone toward the surface of the integrated circuit.

4. The integrated circuit of claim 1, wherein the crack energy release zone comprises a plurality of adjacent metal structures having gaps between them that are not aligned along a first axis to encourage the crack to propagate in a meandering path rather than straight along the first axis.

5. The integrated circuit of claim 4, wherein the first axis comprises a more direct path toward the active area than a second axis perpendicular to the first axis.

6. The integrated circuit of claim 4, wherein the plurality of adjacent metal structures have a length longer along a second axis perpendicular to the first axis and a width along the first axis that is smaller than the length along the second axis.

7. The integrated circuit of claim 1, wherein the crack take-off zone comprises a plurality of metal structures configured to guide the crack toward the surface of the integrated circuit.

8. The integrated circuit of claim 7, wherein the crack take-off zone comprises a sacrificial crack propagation path between the plurality of metal structures.

9. The integrated circuit of claim 8, wherein the sacrificial crack propagation path comprises:
in a first region nearer to a separation line, a first sacrificial layer comprising a first space without one of the plurality of metal structures, wherein the first sacrificial layer is beneath at least a first of the plurality of metal structures; and
in a second region farther from the separation line, a second sacrificial layer comprising a second space without one of the plurality of metal structures, wherein the second sacrificial layer is above at least a second of the plurality of metal structures;
wherein the first sacrificial layer is located nearer to a silicon substrate than the second sacrificial layer, thereby causing the sacrificial crack propagation path to traverse a slope over z- and x-directions.

10. The integrated circuit of claim 7, wherein the crack take-off zone comprises at least one air gap structure to guide the crack toward the surface of the integrated circuit.

11. The integrated circuit of claim 1, wherein the scribe lane comprises test circuitry and wherein the crack energy release zone or the crack take-off zone, or both, are disposed around the test circuitry to protect the test circuitry from damage in the event that the crack were to form.

12. The integrated circuit of claim 1, wherein the crack energy release zone or the crack take-off zone, or both, comprise a staggered pattern of metal structures in a 45°/135° arrangement.

13. A method comprising:
patterning a first metal layer with a first set of staggered features in a scribe lane between two integrated circuit active areas;
patterning a first via layer with a first set of staggered vias connected to at least some of the first set of staggered features of the first metal layer in the scribe lane; and
patterning a second metal layer with a second set of staggered features in the scribe lane, at least some of which are joined to the first set of staggered vias of in the scribe lane, thereby creating an energy release zone of the scribe lane to enable fracture energy to dissipate in an event that a crack were to form in the scribe lane.

14. The method of claim 13, wherein the first metal layer is patterned with the first set of staggered features and the second metal layer is patterned with the second set of staggered features, wherein the first set of staggered features and the second set of staggered features are identical.

15. The method of claim 14, comprising patterning a second via layer with a second set of staggered vias connected to at least some of the second set of staggered features of the second metal layer, wherein the second set of staggered vias are offset in an at least one axis from the first set of staggered vias.

16. The method of claim 14, wherein the first metal layer is patterned with the first set of staggered features and the second metal layer is patterned with the second set of staggered features, wherein the first set of staggered features and the second set of staggered features are different.

17. The method of claim 16, wherein the second set of staggered features has more smaller features than the first set of staggered features.

18. A method comprising:
patterning a first metal layer in a scribe lane of a silicon wafer with a first metal structure; and
patterning a second metal layer in the scribe lane of the silicon wafer with a second metal structure, wherein the first and second metal structures are configured to guide, in an event that a crack were to form in the scribe lane, the crack out toward a surface of the silicon wafer.

19. The method of claim 18, wherein the first metal layer comprises a lower metal layer and the second metal layer comprises an upper metal layer, wherein space between the first and second metal structures forms a sacrificial pathway to enable the crack to pass through toward the surface of the silicon wafer.

20. The method of claim 18, comprising patterning a plurality of additional metal layers comprising additional metal structures configured to guide, in the event that a crack were to form in the scribe lane, the crack out toward a surface of the silicon wafer in concert with the first metal structure and the second metal structure.

21. The method of claim 18, comprising patterning an air gap structure to form a sacrificial pathway to enable the crack to pass through toward the surface of the silicon wafer.

22. The method of claim 21, wherein patterning the air gap structure comprises patterning the air gap structure in a redistribution layer (RDL) of the scribe lane.

23. The method of claim 21, wherein patterning the air gap structure comprises patterning a plurality of additional air gap structures.
